(19) United States
(12) Patent Application Publication
(10) Pub. No.: US 2013/0156597 A1
(43) Pub. Date: Jun. 20, 2013

(54) MOUNTING MECHANISM FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/340,683

(22) Filed: Dec. 30, 2011

(30) Foreign Application Priority Data
Dec. 20, 2011 (CN) 201110429536.1

(51) Int. Cl. F04D 29/00; H05K 7/20; F16M 13/02

(52) U.S. Cl. 416/244 R; 248/674

(57) ABSTRACT

A mounting mechanism is used to mount a fan to a chassis. The mounting mechanism includes parallel first and second guide rails fixed to the chassis, and a mounting bracket fixed to the fan. The fan is slidably sandwiched between the first and second guide rails. The mounting bracket comprises a securing tab detachably and selectively fixed to a position on the first guide rail.

### BACKGROUND

1. Technical Field

The present disclosure relates to a mechanism for mounting a fan.

2. Description of Related Art

In electronic devices, fans may be used to assist in dissipating heat generated by components mounted on circuit boards of the electronic devices. Generally, the fans are fixed in the chassis and cannot be moved in the chassis. As a result, if the components are relocated, the fans may not dissipate heat so effectively.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting mechanism, together with a fan.

FIG. 2 is an enlarged view of the encircled portion II of FIG. 1.

FIG. 3 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

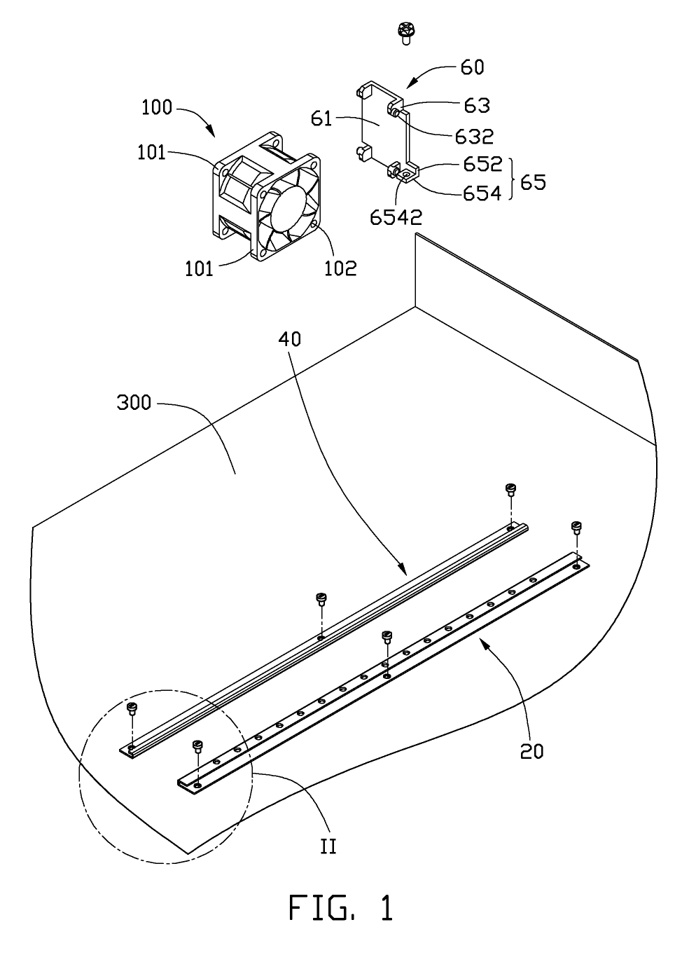

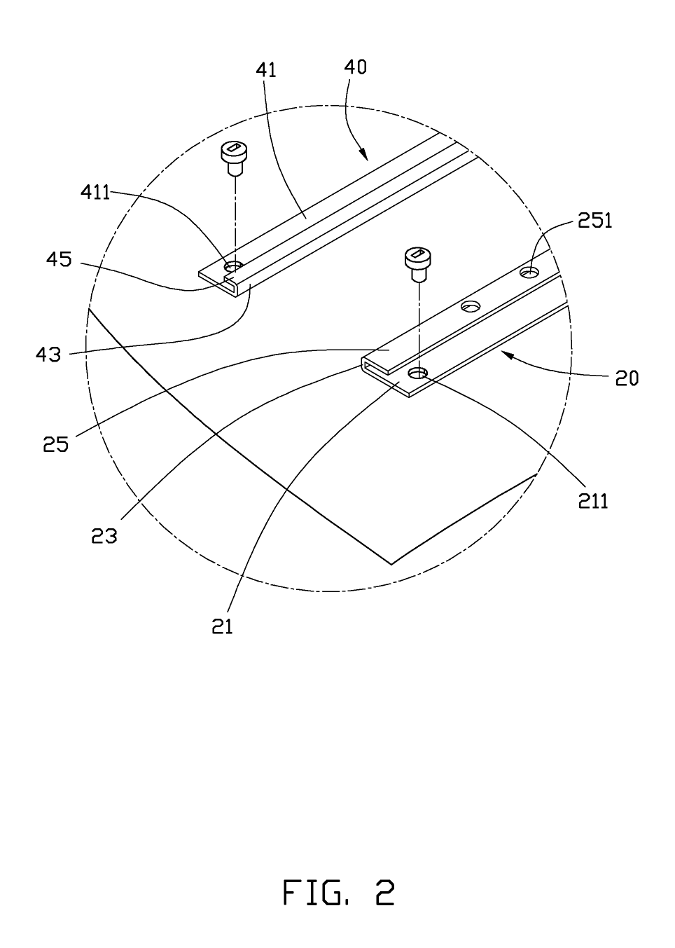

FIGS. 1 and 2, show an exemplary embodiment of a mounting mechanism for fixing a fan 100 including a chassis 300, a first guide rail 20, a second guide rail 40, and a mounting bracket 60.

The fan 100 includes opposite rectangular end boards 101, each defining four mounting holes 102.

The first guide rail 20 includes a lengthwise fixing wall 21, an abutting wall 23 perpendicularly extending up from a side of the fixing portion 21, and a positioning wall 25 perpendicularly extending from a top of the abutting wall 23 and parallel to the fixing wall 21. The fixing wall 21 defines a plurality of fixing holes 211. The positioning wall 25 defines a plurality of internally threaded positioning holes 251, which are equidistantly arranged.

The second guide rail 40 is similar to the first guide rail 20. The second guide rail 40 includes a fixing wall 41, an abutting wall 43 perpendicularly extending up from a side of the fixing wall 41, and a positioning wall 45 perpendicularly extending from a top of the abutting wall 43. The fixing wall 41 defines a plurality of fixing holes 411.

The mounting bracket 60 includes a substantially rectangular main body 61, four mounting tabs 63 perpendicularly extending from a side of the main body 61 and correspondingly adjacent to four corners of the main body 61, and a securing tab 65 extending from the main body 61 adjacent to one of the mounting tabs 63 at a bottom of the main body 61. A column 632 perpendicularly extends from an outer side surface of each of the mounting tabs 63. The securing tab 65 is L-shaped, and includes an extension portion 652 coplanar with the main body 61, and a securing portion 654 perpendicularly extending from a bottom of the extension portion 652. The securing portion 654 defines a fastening hole 6542.

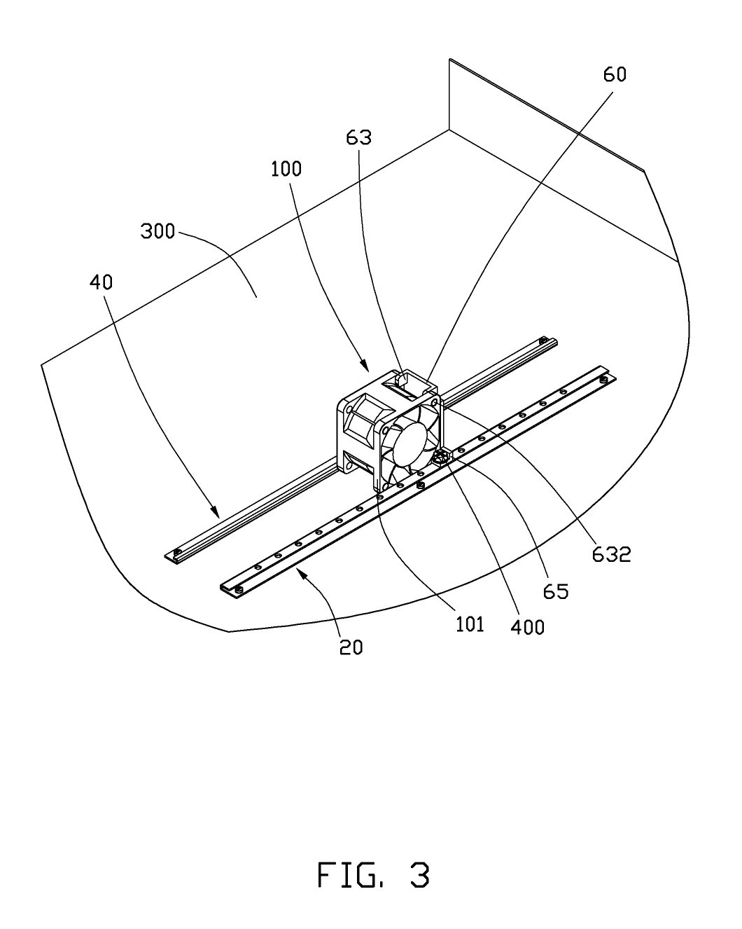

FIG. 3, shows in assembly, the first and second guide rails 20 and 40 are fixed to the chassis 300 with a plurality of fasteners, such as screws or rivets, extending through the fixing holes 211 and 411, and fastened to the chassis 300. The first and second guide rails 20 and 40 are parallel to each other, with a side of the abutting wall 23 opposite to the fixing wall 21 facing a side of the abutting wall 43 opposite to the fixing wall 41. A distance between the abutting walls 23 and 43 is slightly greater than a distance between the end boards 101 of the fan 100. The mounting bracket 60 is manipulated to place the mounting tabs 63 between the end boards 101. The columns 632 are engaged in the corresponding mounting holes 102. Therefore, the mounting bracket 60 is attached to a side of the fan 100. The fan 100 is sandwiched between the first and second guide rails 20 and 40, with the end boards 101 correspondingly abutting against the abutting walls 23 and 43. The securing tab 65 is supported on the positioning wall 25. The fastening hole 6542 is aligned with one of the positioning holes 251. A screw 400 extends through the fastening hole 6542 and is engaged in the positioning hole 251 to position the fan 100 at a desired position.

To relocate the fan 100, the screw 400 is disengaged from the fastening hole 6542. The fan 100 is slid along the first and second guide rails 20 and 40. When the fan 100 reaches a desired position, the screw 400 extends through the fastening hole 6542 and is engaged in a corresponding positioning hole 251 to fix the fan 100 at the desired position.

Even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A mounting mechanism to fix a fan to a chassis, the mounting mechanism comprising:
a first guide rail fixed to the chassis;
a second guide rail fixed to the chassis and parallel to the first guide rail, to sandwich the fan together with the first guide rail; and
a mounting bracket fixed to the fan and comprising a securing tab detachably and selectively fixed to a position on the first guide rail.

2. The mounting mechanism of claim 1, wherein the first guide rail comprises a first fixing wall fixed to the chassis and a first abutting wall perpendicularly extending up from a side of the first fixing wall adjacent to the second guide rail, the second guide rail comprises a second fixing wall fixed to the chassis and a second abutting wall perpendicularly extending up from a side of the second fixing wall adjacent to the first guide rail, the first and second abutting walls corresponding abut against opposite sides of the fan.

3. The mounting mechanism of claim 2, wherein the first guide rail further comprises a positioning wall perpendicularly extending from a top of the first abutting wall opposite to the second abutting wall to fix the securing tab of the mounting bracket.

4. The mounting mechanism of claim 3, wherein a plurality of positioning holes is defined in the positioning wall, and arranged along a lengthwise direction of the first guide rail, the securing tab defines a fastening hole, a screw extends through the fastening hole and is selectively engaged in one of the positioning holes.

5. A fan assembly mounted in a chassis, the fan assembly comprising:
a first guide rail fixed to the chassis;
a second guide rail fixed to the chassis, and parallel to the first guide rail;
a fan slidably sandwiched between the first and second guide rails, and comprising opposite end boards correspondingly abutting against the first and second guide rails; and
a mounting bracket fixed to the fan, and comprising a securing tab detachably and selectively fixed to a position on the first guide rail.

6. The fan assembly of claim 5, wherein each of the end boards defines a plurality of mounting holes, the mounting bracket comprises a plate-shaped main body and a plurality of mounting tabs perpendicularly extending from a side of the main body, a column perpendicularly extends from each of the mounting tabs, the mounting tabs are placed between the end boards of the fan, each of the columns is engaged in one of the mounting holes of the fan.

7. The fan assembly of claim 5, wherein the first guide rail comprises a first fixing wall fixed to the chassis and a first abutting wall perpendicularly extending up from a side of the first fixing wall, the second guide rail comprises a second fixing wall and a second abutting wall perpendicularly extending up from a side of the second fixing wall, the first and second abutting walls corresponding abut against the end boards of the fan.

8. The fan assembly of claim 7, wherein a side of the first abutting wall opposite to the first fixing wall faces a side of the second abutting wall opposite to the second fixing wall.

9. The fan assembly of claim 7, wherein the first guide rail further comprises a positioning wall perpendicularly extending from a top of the first abutting wall to fix the securing tab of the mounting bracket.

10. The fan assembly of claim 9, wherein a plurality of positioning holes is defined in the positioning wall, and arranged along a lengthwise direction of the first guide rail, the securing tabs defines a fastening hole, a screw extends through the fastening hole and is selectively engaged in one of the positioning holes.
